(19) United States
(12) Patent Application Publication
(10) Pub. No.: US 2007/0085577 A1
(43) Pub. Date: Apr. 19, 2007

(54) High frequency transmission gate buffer

(75) Inventor: Stanley J. Goldman, Dallas, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/253,486

(22) Filed: Oct. 18, 2005

(51) Int. Cl. H03B 1/00

(52) U.S. Cl. 327/112

(57) ABSTRACT

An apparatus for providing a signal to a transmission medium. A first switching stage is connected in series between a source voltage and a transmission medium, and a second switching stage connected in series between the transmission medium and a reference line. The first and second switching stages each comprise at least one p channel transistor in parallel with at least one n channel transistor. The first and second switching stages are preferably configured to substantially symmetrically drive the transmission medium at a frequency of at least 4 gigahertz (GHz). The stages are further preferably characterized as variable resistance stages with lower resistance at the rails as compared to the midpoint of the input signal. Additional sets of stages can be provided to facilitate multiple outputs.

### FIELD OF THE INVENTION

The claimed invention relates generally to the field of signal transmission and more particularly, but not by way of limitation, to a high frequency transmission gate buffer device.

### BACKGROUND

Buffers are generally used in electronic circuitry to facilitate transmission of a time-varying signal from a first device to a second device.

FIG. 1 shows a tri-state output buffer (“buffer”) 100 in accordance with the prior art. A p channel switching device 102 is connected in series between a voltage source 104 and a transmission medium 106. An n channel switching device 108 is connected in series between the transmission medium 106 and a reference line 110.

The p channel and n channel switching devices 102, 108 are preferably characterized as PMOS and NMOS transistors, respectively. The transmission medium 106 preferably comprises a 50 ohm coaxial line which terminates at a load 112, but can take other forms including signal traces or nodes on a substrate, a wireless medium, etc. The voltage source 104 is at a suitable source voltage such as +1.2 volts, and the reference line 110 is at a suitable reference voltage such as ground (nominally 0 volts).

A driver circuit 114 receives an input signal (INPUT) on signal path 116 and an enable signal (ENZ) on line (“enable line”) 118. These signals are respectively provided to a number of logic gates including inverters 120, NOR gate 122, and NAND gate 124. The input signal is contemplated as comprising a high speed time varying signal of selected frequency with rail voltages corresponding to the voltage source 104 and reference line 110.

The buffer 100 is enabled low; that is, placing the enable line 118 at the reference voltage (low) causes transmission of an output signal to the transmission medium 106 that nominally corresponds to the input signal on signal path 116. Placing the enable line 118 at the source voltage (high) places the buffer 100 in a high impedance (tri-state) condition. The PMOS transistor 102 will often be provided with a significantly higher areal size as the NMOS transistor 108 (e.g., a ratio of 2.5:1 or so) in order to improve output signal characteristics.

The tri-state output buffer 100 of FIG. 1, has generally been found operable in a number of applications, but transmission line reflections and other limitations have generally limited the viability of this type of buffer architecture at higher frequencies (e.g., above around 1 gigahertz (GHz), or so) and lower source voltages.

FIG. 2 shows a current steering differential output buffer 130 in accordance with the prior art. The buffer 130 provides differential outputs on two separate transmission mediums 106 (OUTPUT A, OUTPUT B), although only one could be used as desired as in FIG. 1.

For each output, n channel switching devices (NMOS transistors) 132 and current limiting resistors 133 are connected in series between a current steering circuit 134 and the reference line 110. The current steering circuit 134 includes a current source 136, relatively small p channel control devices (PMOS transistors) 138 and a relatively large p channel device (PMOS tail current transistor) 140. A driver circuit 142 is also provided generally as before.

Respective inputs to the current steering circuit 134 and the driver circuit 142 include the input signal (INPUT) on path 144, a first enable signal (ENZ) on path 146, a second inverted enable signal (EN) on path 148, and a source voltage from the voltage source 104 on path 149. During operation, the NMOS transistors 132 are selectively operated to “steer” current from the current source 136 to the respective outputs (OUTPUT A and OUTPUT B) in relation to the input signal level.

While providing improved performance as compared to the buffer 100 of FIG. 1, there are nevertheless limitations associated with this type of buffer architecture as well. Depending on the application, the voltage drop across the PMOS tail current transistor 140 can be significant (e.g., on the order of 0.5 volts or so), which reduces the output swing in the output signals on the transmission medium 106. This is generally not a significant problem with higher source voltages, but becomes increasingly disadvantageous and ineffective with lower source voltages (e.g., 1.2 volts).

The current steering differential output buffer 130 also accommodates higher input frequencies than the tri-state output buffer 100 of FIG. 1, but nevertheless has generally been found to have a practical upper limit of around 2 GHz or so.

Accordingly, with continued increases in signal data transmission rates, there is a corresponding need for improved output buffer designs with higher frequency transmission capabilities.

### SUMMARY OF THE INVENTION

Preferred embodiments of the present invention are generally directed to an apparatus for providing a signal to a transmission medium.

The apparatus preferably comprises a first switching stage connected in series between a source voltage and a transmission medium, and a second switching stage connected in series between the transmission medium and a reference line. The first and second switching stages each preferably comprise at least one p channel transistor in parallel with at least one n channel transistor.

Preferably, the first switching stage comprises a first p channel transistor connected in parallel with a first n channel transistor so that a source terminal of the first p channel transistor is connected in series with a drain terminal of the first n channel transistor, and a drain terminal of the first p channel transistor is connected in series with a source terminal of the first n channel transistor.

The first and second switching stages are further preferably configured to substantially symmetrically drive the transmission medium at a frequency of at least 4 gigahertz.

The voltage source preferably comprises a first and second rail (such as 0 and 1.2 volts). During operation, a resistance across the first switching stage operating at each the first and second rails is a substantially common resistance, and a resistance across the first switching stage operating between the first and second rails is greater than the substantially common resistance.

In this way, charge injection and transmission line reflections are reduced, which facilitates the propagation of signals at higher transmission rates.

These and various other features and advantages which characterize the claimed invention will become apparent upon reading the following detailed description and upon reviewing the associated drawings.

### BRIEF DESCRIPTION OF THE DRAWINGS

FIG. 1 is a generalized schematic diagram for a tri-state output buffer constructed in accordance with the prior art.

FIG. 2 is a generalized schematic diagram for a current steering differential output buffer in accordance with the prior art.

FIG. 3 provides a generalized schematic diagram for a high frequency transmission gate buffer constructed in accordance with preferred embodiments of the present invention.

FIG. 4 shows a preferred embodiment of one of the switching (variable resistance) stages of FIG. 3 in greater detail.

FIG. 5 shows an alternate preferred embodiment of one of the switching (variable resistance) stages of FIG. 3 in greater detail.

FIG. 6 is a graphical representation of output characteristics of the respective buffers of FIGS. 1-3 for an input signal of about 8 GHz.

FIG. 7 is a graphical representation of output characteristics of the respective buffers of FIGS. 1-3 for an input signal of about 4 GHz.

FIG. 8 shows respective resistance characteristics of the respective buffers of FIGS. 1 and 3.

### DETAILED DESCRIPTION

FIG. 3 provides a generalized schematic representation of a high frequency transmission gate buffer (“buffer”) 150 constructed in accordance with preferred embodiments of the present invention.

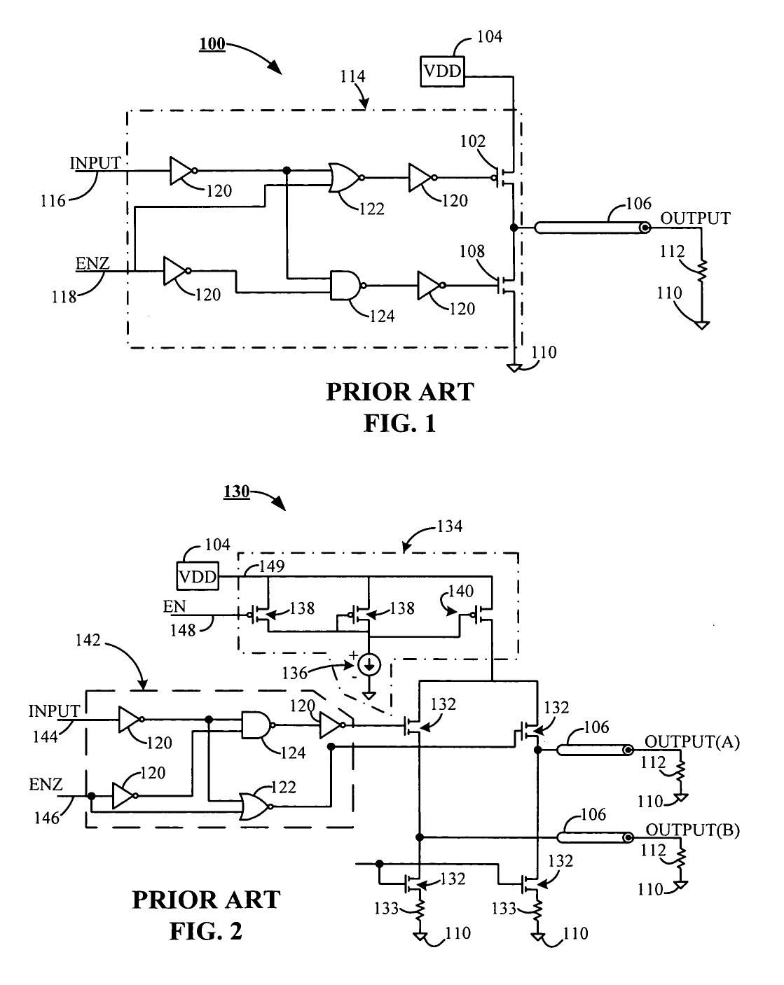

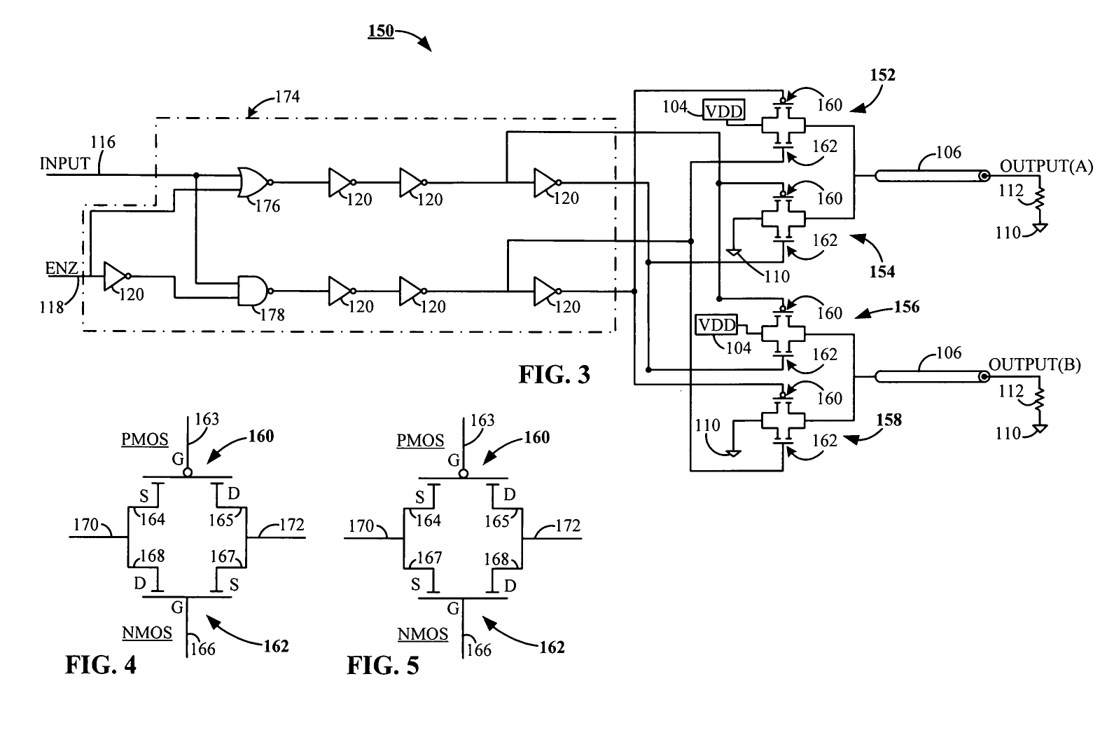

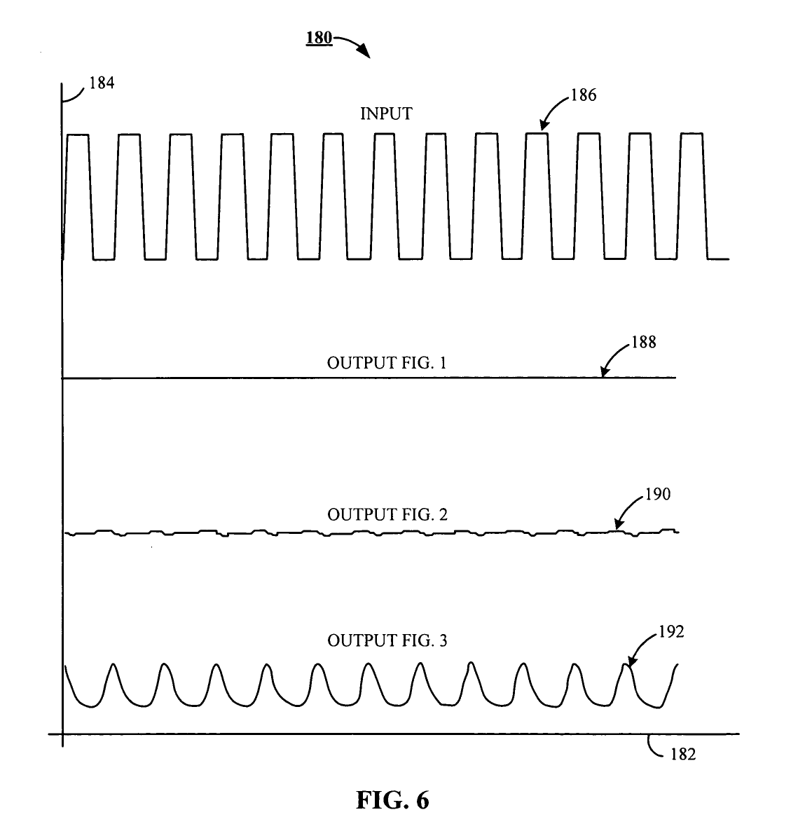

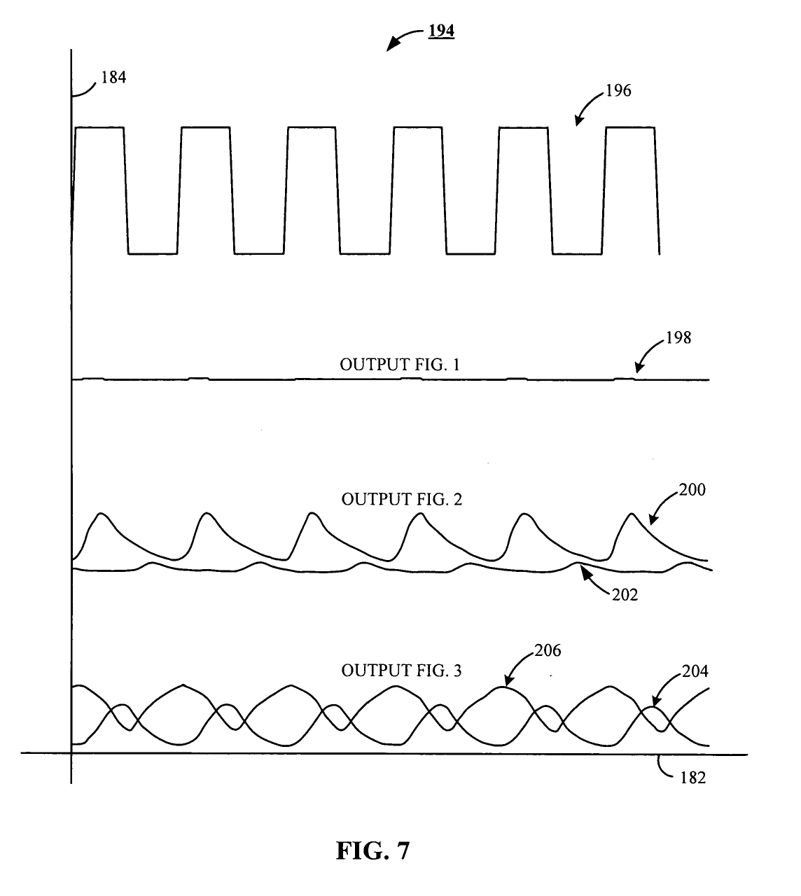

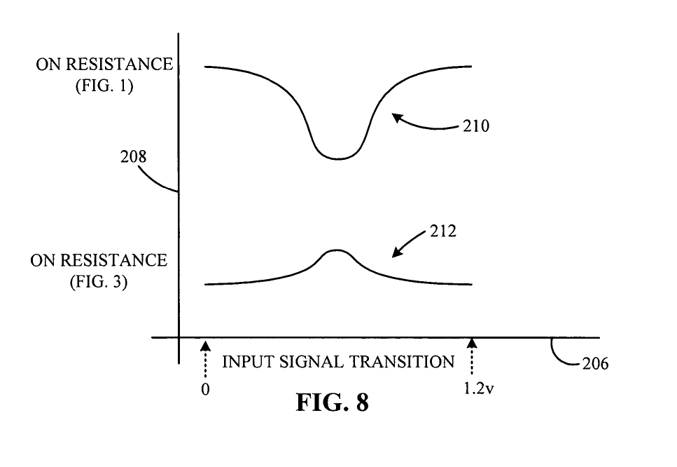

The buffer 150 is suitable for any number of signal transmission applications, including applications with transmission frequencies of 4 GHz or higher. For convenience, like reference numerals are used in FIG. 3 to identify similar components previously introduced in FIGS. 1 and 2.

The buffer 150 preferably includes a first switching stage 152 connected in series between the voltage source 104 and transmission medium 106 [OUTPUT (A)], and a second switching stage 154 connected in series between the transmission medium 106 and reference line 110.

The midpoint between the first and second switching stages 152, 154 comprises an output terminal that is coupleable to the transmission medium 106, so that the transmission medium 106 can be permanently affixed, or selectively connected and removed from the buffer 150 as desired. For purposes of the present discussion, it will be contemplated that the transmission medium 106 comprises a 50 ohm coaxial transmission line, although such is not limiting. It is further noted that the term switching stage is also referred to herein as a transmission gate.

The buffer 150 is shown to be provisioned with two outputs (OUTPUT A, B) so that third and fourth switching stages 156, 158 are coupled with the voltage source 104, reference line 110, and a second transmission medium 106 [OUTPUT (B)] as shown. This second output can be useful in differential signal applications, but is not required.

FIG. 4 shows each of the respective switching stages 152-158 to preferably comprise a p channel (PMOS) transistor 160 connected in parallel with an n channel (NMOS) transistor 162. The PMOS and NMOS transistors 160, 162 have respective gate, source, and drain terminals 163(G), 164(S), 165(D) and 166(G), 167(S), 168(D). The PMOS source 164(S) is preferably connected in series with the NMOS drain 168(D), and the PMOS drain 165(D) is preferably connected in series with the NMOS source 167(S) as shown.

A low level at the PMOS gate 163(G) provides a low impedance path between source 164(S) and drain 165(D), and a high level at the NMOS gate 166(G) establishes a low impedance path between source 167(S) and drain 168(D). As explained below, the gate voltages are selected to cause the respective devices 158, 160 to nominally operate in tandem so that both devices are either conductive, or both devices present a high impedance between lines 170 and 172. Preferably, the PMOS transistor 160 has the same areal size as the complementary NMOS transistor 162.

However, one skilled in the art will recognize that the gate, source, and drain terminals 163(G), 164(S), 165(D) and 166(G), 167(S), 168(D) may have a plurality of alternate operative configurations, each of which are contemplated by the present invention. FIG. 5 shows one such an alternate configuration, where the PMOS source 164(S) is preferably connected in series with the NMOS source 167(S), and the PMOS drain 165(D) is preferably connected in series with the NMOS drain 168(D) as shown.

Referring again to FIG. 3, a driver circuit 174 receives an input signal (INPUT) on signal path 116 and an enable (ENZ) signal on enable line 118, and provides outputs to the various gate terminals of the respective switching stages 152-158. The driver circuit 174 can take any number of desired forms, and is preferably shown to include a number of inverters 120 as well as an OR gate 176, and AND gate 178. A low enable signal (provided on enable line 118) results in complementary output signals on the respective transmission medium 106 (OUTPUTS A and B), in relation to the input signal provided on signal path 116, and a high enable signal tri-states the buffer 150.

The buffer 150 (of FIG. 3) provides a significantly improved response as compared to the prior art buffers 100, 130 of FIGS. 1 and 2. By way of illustration, device performance curves 180 of FIG. 6 provides a sequence of curves for the respective devices of FIGS. 1-3, plotted against an elapsed time x-axis 182 and a common amplitude y-axis 184.

An input signal of nominally 8 GHz is represented at 186. Curve 188 represents the output from the buffer 100 of FIG. 1, which shows no variation in amplitude of the output signal, accordingly, the output signal cannot be discerned. Curve 190 represents the output from the buffer 130 of FIG. 2, which shows an output having insubstantial and erratic amplitude, and accordingly the output from the buffer 130 is non-discernable. Curve 192 represents the output from the buffer 150 of FIG. 3.

It can be seen that the prior art buffers 100 and 130 saturate, or are otherwise unable to provide a discernable output signal at a nominal frequency of substantially 8 GHz, whereas the curve 192 can be readily detected using a spectrum analyzer or similar detection circuitry. While the output signal from the buffer 150 (curve 192) is not symmetric and has a relatively low peak to peak range (on the order of 5 millivolts, (mv pp)), the signal is nevertheless useful for testing, or other operational purposes.

FIG. 7 shows a corresponding sequence of device performance curves 194 for an input signal at 4 GHz (curve 196). As before, the output of the buffer 100 of FIG. 1 is saturated (curve 198). The current steering differential buffer 130 of FIG. 2 provides asymmetric output curves 200, 202, with curve 202 (OUTPUT B) having a substantially lower peak to peak range. Curves 204 and 206 correspond to the respective outputs of the buffer 150 of FIG. 3, and are shown to be both substantially symmetric and have a peak to peak voltage swing of greater than 500 mv pp.

One reason for the significantly enhanced performance of the buffer 150 of FIG. 3 is that charge injection is minimized. As one switching stage (e.g., 152) turns off, the other switching stage (e.g., 154) turns on, which provides an alternate path for the charge in the off transistors to travel. This significantly reduces reflections on the output transmission medium 106.

Each of the switching stages 152-158 (FIGS. 3 and 4) further preferably operate as a variable resistance stage, with improved resistance characteristics at the rails as compared to the prior art. FIG. 8 shows a generalized comparison between the prior art buffer 100 of FIG. 1 and the buffer 150 of FIG. 3. An x-axis 206 represents one-half of the input signal duty cycle; that is, the transition of the input signal from the reference voltage level (0 v) to the source voltage level (1.2 v). A y-axis 208 generally represents relative on-resistance of the respective switching devices/stages.

Curve 210 corresponds to the prior art buffer 100, and shows the prior art buffer 100 to have a significantly higher resistance when the input signal is near the rails as compared to the midpoint voltage. By contrast, curve 212 corresponds to the buffer 150. Not only is the resistance lower at the rails than at the midpoint, but the overall resistance range is also significantly reduced as compared to curve 210.

From the foregoing it will now be understood that preferred embodiments of the present invention present advantages over the prior art. The use of at least one p channel device in parallel with at least one n channel device in each switching stage reduces charge injection effects as the devices transition between conductive and non-conductive states. Charge needed to change state in one device can be supplied, at least in part, by the complementary device, reducing unwanted disturbances on the transmission medium 106.

Also, the novel arrangement disclosed herein provides an improved resistance profile that can further be tailored as desired to the characteristics of the transmission medium 106.

Accordingly, preferred embodiments of the present invention are generally directed to an apparatus for providing a signal to a transmission medium 106.

In some preferred embodiments, the apparatus can be characterized as a first switching stage (such as 152, 156) connected in series between a voltage source (such as 104) and a transmission medium (such as 106), and a second switching stage (such as 154, 158) connected in series between the transmission medium and a reference line (such as 110), wherein the first and second switching stages each comprise at least one p channel transistor (such as 160) in parallel with at least one n channel transistor (such as 162).

Preferably, the first switching stage comprises a first p channel transistor connected in parallel with a first n channel transistor so that a source terminal (such as 164) of the first p channel transistor is connected in series with a drain terminal (such as 168) of the first n channel transistor, and a drain terminal (such as 165) of the first p channel transistor is connected in series with a source terminal (such as 167) of the first n channel transistor.

The first and second switching stages are further preferably configured to substantially symmetrically drive the transmission medium at a frequency of at least 4 gigahertz (such as at 204, 206).

The voltage source preferably comprises a first and second rail (such as 0 and 1.2 volts), and wherein during operation of the first switching stage a resistance across the first switching stage operating at each the first and second rails is a substantially common resistance, and a resistance across the first switching stage operating between the first and second rails is greater than the substantially common resistance operating at each the first and second rails.

It is to be understood that even though numerous characteristics and advantages of various embodiments of the present invention have been set forth in the foregoing description, together with details of the structure and function of various embodiments of the invention, this detailed description is illustrative only, and changes may be made in detail, especially in matters of structure and arrangements of parts within the principles of the present invention to the full extent indicated by the broad general meaning of the terms in which the appended claims are expressed. For example, the particular elements may vary depending on the particular device environment without departing from the spirit and scope of the present invention.

What is claimed is:

1. An apparatus comprising a first switching stage connected in series between a source voltage and a transmission medium, and a second switching stage connected in series between the transmission medium and a reference line, wherein the first and second switching stages each comprise at least one p channel transistor in parallel with at least one n channel transistor.

2. The apparatus of claim 1, wherein the first switching stage comprises a first p channel transistor connected in parallel with a first n channel transistor so that a source terminal of the first p channel transistor is connected in series with a drain terminal of the first n channel transistor, and a drain terminal of the first p channel transistor is connected in series with a source terminal of the first n channel transistor.

3. The apparatus of claim 2, wherein the second switching stage comprises a second p channel transistor connected in parallel with a second n channel transistor so that a source terminal of the second p channel transistor is connected in series with a drain terminal of the second n channel transistor and a drain terminal of the second p channel transistor is connected in series with a source terminal of the second n channel transistor.

4. The apparatus of claim 1, wherein the second switching stage comprises a second p channel transistor connected in parallel with a second n channel transistor so that a source terminal of the second p channel transistor is connected in series with a drain terminal of the second n channel transistor, and a drain terminal of the second p channel transistor is connected in series with a source terminal of the second n channel transistor.

5. The apparatus of claim 1, wherein the at least one p channel transistor comprises a first p channel transistor, and wherein the at least one n channel transistor comprises a first n channel transistor, and further wherein the first p channel transistor is nominally the same areal size as the first n channel transistor.

6. The apparatus of claim 1, wherein the first and second switching stages are configured to substantially symmetrically drive the transmission medium at a frequency of at least 4 gigahertz.

7. The apparatus of claim 1, wherein the voltage source comprises a first and second rail, and wherein during operation of the first switching stage a resistance across the first switching stage operating at each the first and second rails is a substantially common resistance, and a resistance across the first switching stage operating between the first and second rails is greater than the substantially common resistance.

8. The apparatus of claim 1, wherein the first switching stage provides a peak to peak voltage swing of at least 500 millivolts while substantially symmetrically driving the transmission medium at a frequency of at least 4 gigahertz.

9. The apparatus of claim 8, wherein the second switching stage provides a peak to peak voltage swing of at least 500 millivolts while substantially symmetrically driving the transmission medium at a frequency of at least 4 gigahertz.

10. The apparatus of claim 1, further comprising a third switching stage connected in series between the source voltage and a second transmission medium, and a fourth switching stage connected in series between the second transmission medium and the reference line, wherein the third and fourth switching stages each comprise at least one p channel transistor in parallel with at least one n channel transistor.

11. An apparatus comprising a first variable resistance stage connected in series between a source voltage and a transmission medium, and a second variable resistance stage connected in series between the transmission medium and a reference line, wherein the first and second variable resistance stages are configured to substantially symmetrically drive the transmission medium at a frequency of at least 4 gigahertz.

12. The apparatus of claim 11, wherein the first stage comprises a first p channel transistor connected in parallel with a first n channel transistor so that a source terminal of the first p channel transistor is connected in series with a drain terminal of the first n channel transistor, and a drain terminal of the first p channel transistor is connected in series with a source terminal of the first n channel transistor.

13. The apparatus of claim 12, wherein the second stage comprises a second p channel transistor connected in parallel with a second n channel transistor so that a source terminal of the second p channel transistor is connected in series with a drain terminal of the second n channel transistor, and a drain terminal of the second p channel transistor is connected in series with a source terminal of the second n channel transistor.

14. The apparatus of claim 11, wherein the second stage comprises a second p channel transistor connected in parallel with a second n channel transistor so that a source terminal of the second p channel transistor is connected in series with a drain terminal of the second n channel transistor, and a drain terminal of the second p channel transistor is connected in series with a source terminal of the second n channel transistor.

15. The apparatus of claim 11, wherein the voltage source comprises a first and second rail, and wherein during operation of the first switching stage a resistance across the first switching stage operating at each the first and second rails is a substantially common resistance, and a resistance across the first switching stage operating between the first and second rails is greater than the substantially common resistance.

16. The apparatus of claim 11, wherein the first switching stage provides a peak to peak voltage swing of at least 500 millivolts while driving said transmission medium at said frequency of at least 4 gigahertz.

17. The apparatus of claim 16, wherein the second switching stage provides a peak to peak voltage swing of at least 500 millivolts while driving said transmission medium at said frequency of at least 4 gigahertz.

18. The apparatus of claim 11, further comprising a third variable resistance stage connected in series between the source voltage and a second transmission medium, and a fourth variable resistance stage connected in series between the second transmission medium and the reference line, wherein the third and fourth variable resistance stages are configured to substantially symmetrically drive the transmission medium at a frequency of at least 4 gigahertz, wherein each said first, second, third, and fourth stage comprises at least one p channel transistor connected in parallel with a corresponding n channel transistor such that a source terminal of each at least one p channel transistor is connected in series with a drain terminal of its corresponding n channel transistor, and a drain terminal of each at least one p channel transistor is connected in series with a source terminal of its corresponding n channel transistor.

19. An apparatus comprising an output terminal coupleable to a transmission medium, and means for substantially symmetrically driving the transmission medium through the terminal at a frequency of at least 4 gigahertz.

20. The apparatus of claim 19, wherein the means for substantially symmetrically driving the transmission medium through the terminal at a frequency of at least 4 gigahertz comprises a first switching stage connected in series between a source voltage and a transmission medium, and a second switching stage connected in series between the transmission medium and a reference line, wherein the first and second switching stages each comprise at least one p channel transistor in parallel with at least one n channel transistor.
